(19) United States
(12) Patent Application Publication
(10) Pub. No.: US 2007/0218663 A1
(43) Pub. Date: Sep. 20, 2007

(54) Semiconductor device incorporating fluorine into gate dielectric

(75) Inventors: Pinghai Hao, Plano, TX (US); Imran Khan, Richardson, TX (US); Fan-Chi Hou, McKinney, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/384,724

(22) Filed: Mar. 20, 2006

(51) Int. Cl. H01L 21/425

(52) U.S. Cl. 438/532; 257/E21.336

(57) ABSTRACT

The invention provides, in one aspect, a method of fabricating a semiconductor device. This embodiment comprises depositing a gate layer over a gate dielectric layer located over a semiconductor substrate, and incorporating fluorine into the gate dielectric layer before doping the gate layer.

### TECHNICAL FIELD OF THE INVENTION

The invention is directed in general to a semiconductor device, and more specifically, to a semiconductor device incorporating fluorine into the gate dielectric.

### BACKGROUND

Low frequency, or 1/f noise has been a concern in the implementation of high performance analog transistor technology. It is generally accepted that 1/f noise is caused by carriers, such as electrons or holes, being transiently trapped in the gate dielectric or trapped in the interface between the gate dielectric and the channel of a transistor. The random translocation of carriers into traps or defect centers, such as silicon dangling bonds, into the gate dielectric and back into the channel, causes the current through the transistor to fluctuate, which manifests as 1/f noise.

The push toward smaller and faster semiconductor devices has increased the need to reduce 1/f noise. As an example, it is well known that the output noise spectrum (S_{ids}) of 1/f noise from a transistor device increases as an inverse second order function of decreasing effective channel length (i.e., S_{ids} [symbol] 1/L_{eff}²). The increase in 1/f as device area is decreased has especially deleterious consequences for analog-to-digital converter and amplifier applications.

The effect of 1/f noise can be partially mitigated by using transistors having large device areas in the initial stages, so that 1/f noise does not get amplified to the same extent as the signal in subsequent stages of an amplification circuit. This approach, however, does not prevent 1/f noise from being introduced at later amplification stages in the circuit where smaller transistors are used. Moreover, the dimensions to which such devices can be scaled down to are limited by the necessity for one or more large early stage transistors.

Negative Bias Thermal Instability (NBTI) is another concern raised as semiconductor device sizes shrink. NBTI is caused by thermal and voltage stress. The activation temperature can be as low as 100° C., and the minimum necessary gate field strength is below 6 MV/cm. These are conditions routinely experienced by MOSFET transistors in current generation integrated circuits. The changes in transistor performance can significantly degrade circuit performance by causing changes in circuit timing, resulting in increased error rates or even device failure.

A cause of NBTI is the formation of trapped charge at the interface between the gate oxide and the channel. Trapped charge results from the removal of hydrogen at the interface between the channel and the gate dielectric. Hydrogen may be incorporated in the interface as a result of hydrogen containing processes during fabrication. Hydrogen is also intentionally introduced at the end of the fabrication process with a forming gas anneal to reduce un-bonded active bonds (i.e., dangling bonds) at the gate oxide-channel interface. These dangling bonds are a consequence of the crystal lattice mismatch between crystalline silicon in the channel and amorphous silicon dioxide in the gate dielectric. Such bonds will result in trapped charge at the interface unless they are passivated.

Several techniques to reduce NBTI are known, including fluorine implantation of the channel and modification of nitrogen content of nitrided gate oxide. Current fluorine implantation processes, while effective at stabilizing the interface, introduces other detrimental effects, such as enhanced boron diffusion in the gate oxide and higher junction leakage.

Addressing the concurrent problems of 1/f noise and NBTI presents challenges, especially when semiconductor device feature sizes have shrunk to deep sub-micron ranges, e.g., less than 90 nm. Current processes developed to address both 1/f noise and NBTI in larger device sizes are inadequate address these issues.

Accordingly, what is needed is a method of fabricating a semiconductor device that addresses these deficiencies.

### SUMMARY OF INVENTION

The invention, in one aspect, provides a method of fabricating a semiconductor device. An embodiment comprises forming a gate dielectric layer over a semiconductor substrate, depositing a gate layer over the gate dielectric layer, incorporating fluorine into the gate dielectric layer and doping the gate layer after incorporating fluorine into the gate dielectric.

In another embodiment, an integrated circuit is fabricated by forming gate electrodes over a semiconductor substrate that includes depositing a gate layer over a gate dielectric layer and incorporating fluorine into the gate dielectric layer before doping the gate layer. The fabrication further includes forming source/drains within the semiconductor substrate and adjacent the gate electrodes, depositing dielectric layers over the gate electrodes, and forming interconnects within and over the dielectric electrodes to interconnect the gate electrodes and form an integrated circuit.

In another embodiment, a semiconductive device is provided that comprises a gate dielectric layer on a substrate, a gate layer located over the gate dielectric layer, where the gate layer being doped with a dopant, and fluorine incorporated into the gate dielectric layer prior to the gate layer being doped with the dopant.

### BRIEF DESCRIPTION OF THE DRAWINGS

The invention is described with reference to example embodiments and to accompanying drawings wherein:

FIG. 1 illustrates a sectional view of one embodiment of a semiconductor device in accordance with the invention;

FIGS. 2A-2G illustrate various stages of manufacture of an embodiment of the invention;

FIGS. 3A-3C illustrate various stages of manufacture of an alternative embodiment of the invention; and

FIG. 4 illustrates a sectional view of an integrated circuit (IC) incorporating the semiconductor device of the invention.

### DETAILED DESCRIPTION

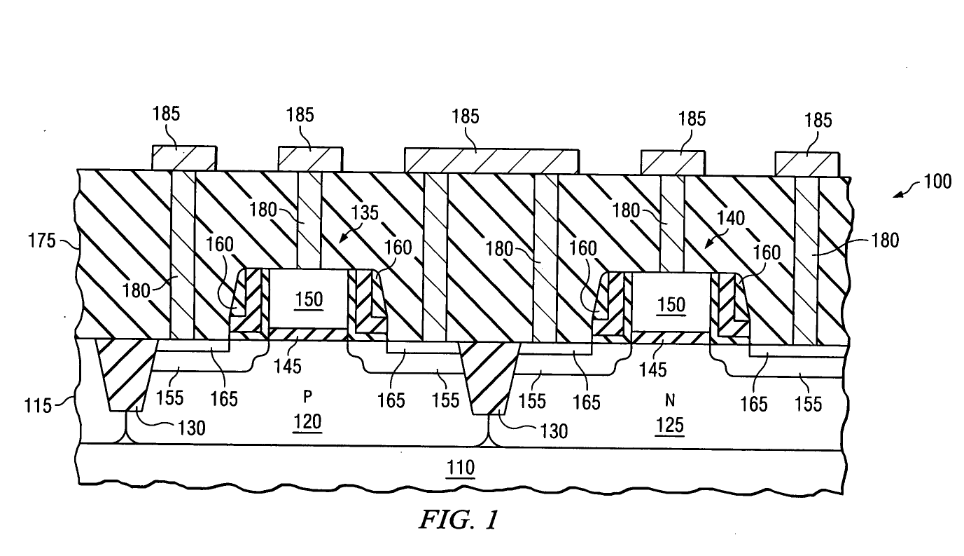

FIG. 1 shows an embodiment of a semiconductor device 100 in accordance with the principles of the invention. Semiconductor device 100 comprises a semiconductor substrate 110. Located over the substrate 110 is an active region 115. Wells 120 and 125 are located in the active layer 115. Isolation structures 130 are also located in the active layer 115.

In the illustrated embodiment, the semiconductor device 100 includes transistors 135, 140. Transistor 135 is an NMOS transistor and transistor 140 is a PMOS transistor. However, various transistor configurations are also within the scope of the invention. The transistors 135, 140 may each comprise source/drains 155 and spacers 160 and silicide contacts 165.

The transistors 135, 140 further include gate dielectric layers 145 over which transistor gate electrodes 150 are located. In the embodiment shown in FIG. 1, the dielectric layers 145 contain fluorine that has been incorporated in accordance with the invention to enhance transistor performance by reducing 1/f noise and NBTI. In other embodiments only one of the gate dielectric layers 145 may contain fluorine.

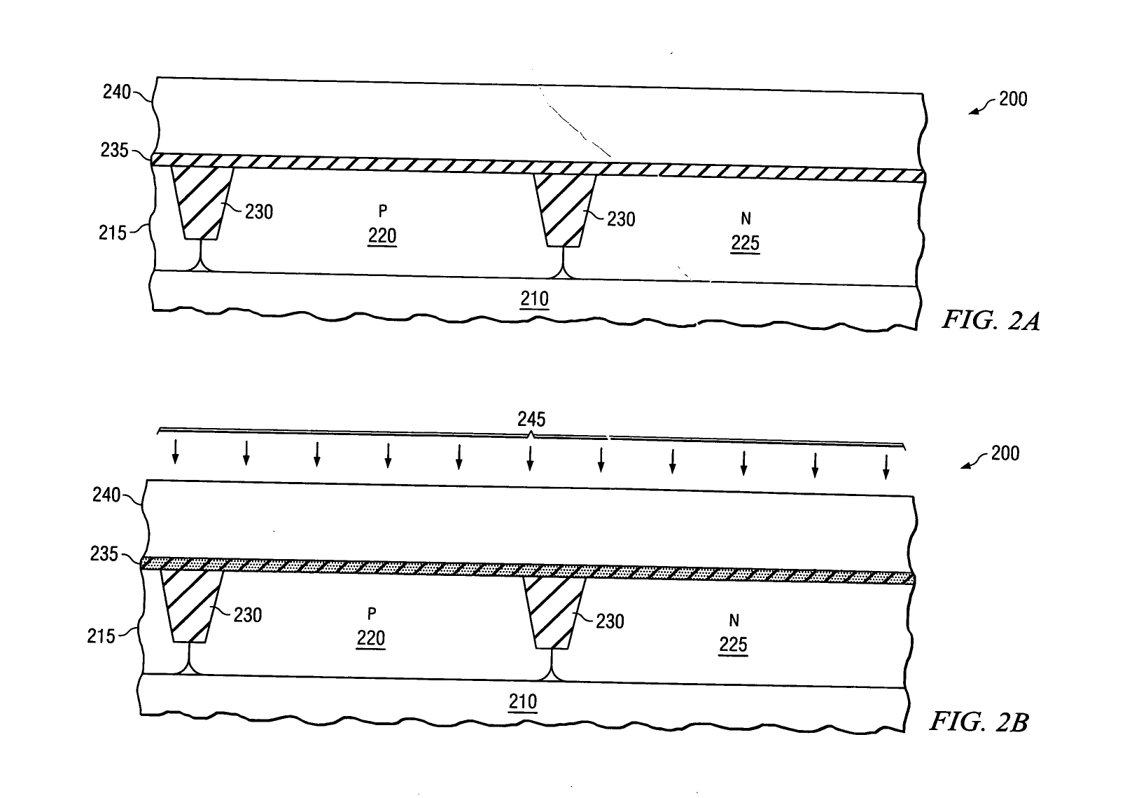

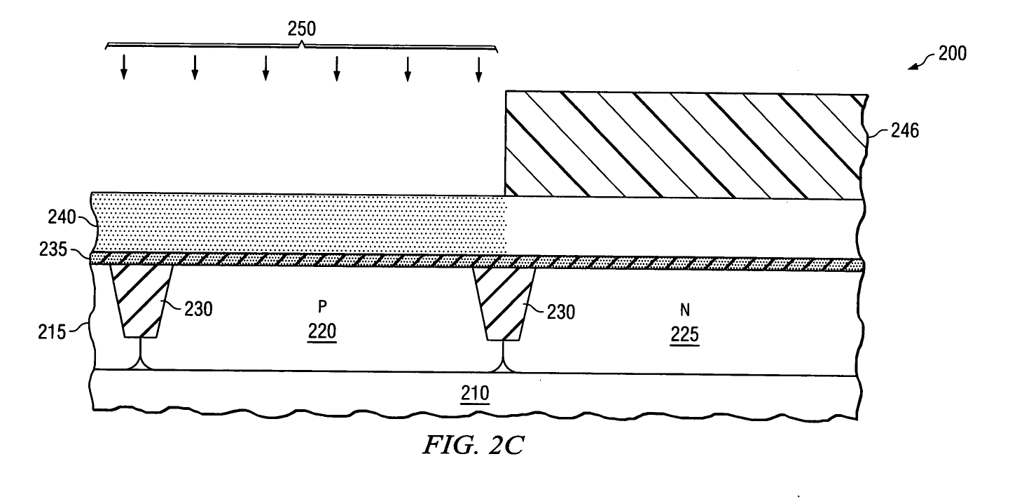

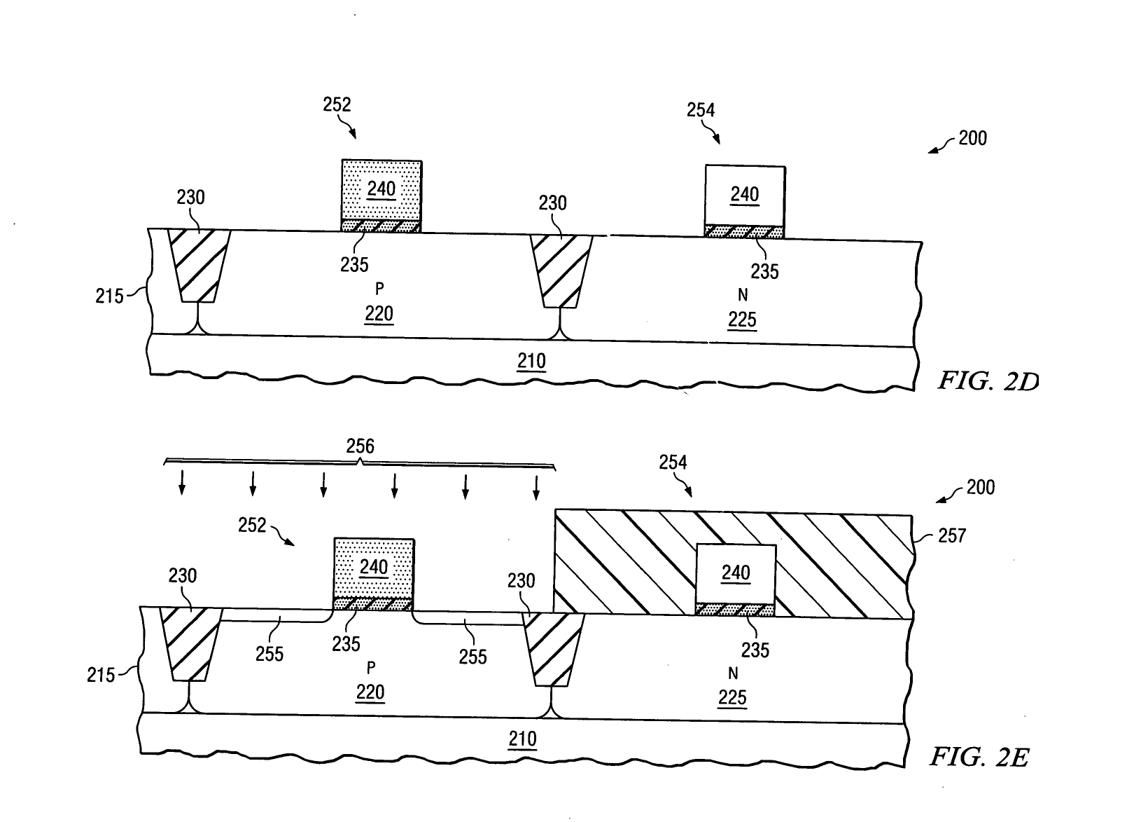

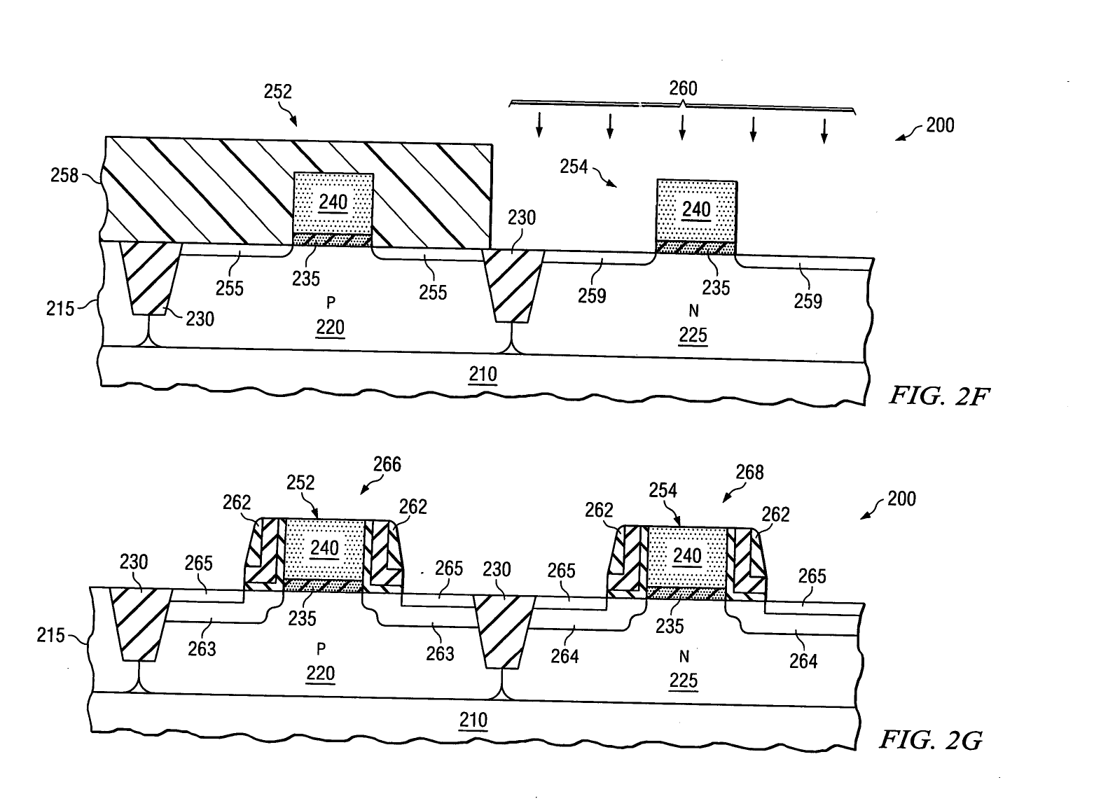

FIG. 2A shows an embodiment of a semiconductor device 200 of the invention at one stage of manufacture. Semiconductor device 200 includes some of the same features as device 100 (numbered similarly). The substrate 210 may be a semiconductor material, such as doped silicon, silicon germanium, or gallium arsenide. An active layer 215 is located over the substrate 210. The active layer 215 may be a portion of the substrate 210 that is doped to function as an active layer for the device 200, or it may be an epitaxial layer. Wells 220, 225 are located within the active layer 215, and they may be doped with the same dopant type, or they may be complementary doped wells, as indicated. Isolation structures 230, such as isolation trenches, electrically isolate wells 220, 225 from each other. Processes or materials known to those skilled in the art may be used to construct these components.

The semiconductor device 200 further includes a gate dielectric layer 235. The thickness of the dielectric layer 235 may vary from one embodiment to another, but in one aspect, its thickness will be about 3.5 nm or less. Conventional processes may be used to form the dielectric layer 245, and it may be comprised of conventional materials. Additionally, it may have a high or low dielectric constant (K), e.g, a dielectric constant that is either higher or lower than silicon dioxide. In one aspect, the layer 245 may be silicon dioxide that has been grown in a thermal oxidizing atmosphere and that results in a high quality silicon dioxide. Alternatively, the layer may be comprised of deposited refractory oxides, such as hafnium oxide, or it may also include other deposited dielectric materials, such as silicon oxynitride.

A gate layer 240 is located over the gate dielectric layer 235. The gate layer 240 may also be comprised of conventional materials, such as polysilicon, and conventional processes, such as chemical vapor deposition (CVD) or physical vapor deposition (PVD), may be used to deposit the gate layer 240. Gate layer 240 may also be a stacked structure that includes other known materials, such as refractory metals and silicides. While the thickness of the gate layer 240 may vary, one embodiment is directed to thicknesses typically associated with submicron technologies, e.g., 80 nm or less. At this point, the gate layer 240 is not doped to a degree sufficient to allow it to function as an operative gate electrode. However, small amounts or trace amounts of gate dopants may be present. Therefore, for purposes of the invention the gate layer 240 is substantially undoped at this point of manufacture.

After the deposition of the gate layer 240, the semiconductor device 200 is subjected to a fluoridation process 245, such as a fluorine implant or fluorine gas diffusion process. As shown in the embodiment of FIG. 2B, the fluorine is incorporated into the gate dielectric layer 235 located over both wells 220, 225. During the process 245, the fluorine is diffused through the gate layer 240 and into the gate dielectric layer 235. In one embodiment, a fluorine dose ranging from about 1e14 atoms/cm² to about 5e15 atoms/cm² may be used and may be followed by a thermal anneal that is conducted at a temperature higher about than 850° C. These fluorine concentrations are lower than those used in conventional processes but are still effective to achieve the desired results in the invention because higher temperatures may be used to diffuse the fluorine into the gate dielectric layer 235 due to the fact that the gate layer 240 is substantially undoped. This is in contrast to conventional processes where higher fluorine dosages have to be used because lower temperatures must be used due to the presence of the gate dopants. However, in the invention, because substantial amounts of gate dopants are not present, lower fluorine dosages and higher temperatures may be used.

Because the gate layer 240 is not substantially doped at the time the fluorine is incorporated into the gate dielectric layer 235, the dopant cannot be diffused into the dielectric layer 235 or the channel region within the active region 215, as in conventional processes. Moreover, the higher temperatures more robustly activate the fluorine without over diffusing the dopant. It has also been found that these higher temperatures improve the interface quality of the gate dielectric layer 235.

The temperature at which the process 245 may be conducted varies depending on the process technology used. However, the process 245 should be conducted at a temperature sufficient to adequately diffuse the fluorine into the gate dielectric layer 235 or to the interface of the gate dielectric layer 235 and the active region 215.

Further, the temperature should be sufficient to activate the fluorine and cause it to replace at least some, if not a substantial portion, of the oxygen within the gate dielectric layer 235; and, thereby, improve the interface quality between the gate layer 240 and the gate dielectric layer 235. Examples of temperatures that may be used to accomplish this include temperatures above about 850° C., with one example being a temperature at or above about 870° C. The implanted dosage of the fluorine will also vary from one embodiment to another.

After the process step 245, the semiconductor device 200 is masked and patterned to expose portions of the gate dielectric layer 235 and gate layer 240 that overlie the well 220, which may be configured as an NMOS device, as seen in FIG. 2C. Conventional lithographic processes and materials may be used to form the patterned mask 246. FIG. 2C also shows the exposed portion of the gate layer 240 being subjected to a gate doping process 250. The patterned mask 246 protects the remaining portion of the semiconductor device 200, as shown. Conventional dopant concentrations and implantation processes may be used to dope the gate layer 240 and activate the dopants at temperatures below the temperatures used to accomplish the fluoridation of the gate dielectric layer 235. In the illustrated embodiment, the dopant may be an n-type dopant, such as arsenic, phosphorous, or a combination of those dopants. Moreover, examples of dopant dosages that may be used range from about 1e15 atoms/cm² to about 1e16 atom/cm² where the dopant is an n-type dopant. The type of dopants that are used will depend on the type of the device. In device features in the submicron range, the temperatures used after the fluorine anneal to complete the fabrication process will typically be less than about 850° C.

FIG. 2D illustrates the semiconductor device 200 following the removal of the pattern mask 246 and patterning of the gate dielectric layer 235 and the gate layer 240 to form gate electrodes 252 and 254. Conventional processes may be used to pattern the gate electrodes 252 and 254. In the illustrated embodiment, which is but one configuration, the gate electrode 252 is doped to serve as a gate electrode for an NMOS device, while the gate electrode 254 is doped to serve as a gate electrode for a PMOS device. It should be noted in this embodiment that due to the fluoridation processes described above, both gate dielectric layers 235 have been fluorinated; this is not the case, however, with all embodiments covered by the invention.

In FIG. 2E, the semiconductor device 200 is patterned for purposes of forming optional source/drain extensions 255, which may be conventionally formed, adjacent the gate electrode 252. The gate electrode 254 is protected from an implantation process 256 by a patterned mask 257, which may also be formed using conventional processes and materials. The type of dopants and dosage concentrations of those dopants will depend on the device. Typically, the source/drain extensions 255 will be lightly doped to form lightly doped drain (LDD) extensions.

As seen in FIG. 2F, following the formation of the source/drain extensions 255, the resist mask 257 is removed and the gate electrode 252 is protected with a patterned mask 258 for purposes of forming optional LDD source/drain extensions 259, which may be conventionally formed, adjacent the gate electrode 254. The gate electrode 252 is protected from an implantation process 260 by the patterned mask 258, which may also be formed using conventional processes and materials. The type of dopants and dosage concentrations of those dopants will depend on the device.

After the formation of the LDD source/drains 255 and 259, in those embodiments where they are present, conventional processes may then be used to form spacers 262, as seen in FIG. 2G. The spacers 260 may comprise a single layer or multiple layers, as shown, and may be constructed with conventional materials, such as oxides, nitrides, or combinations thereof. Conventional deep source/drain implant process may then be conducted to form source/drains 263 and 264 located adjacent the respect gate electrodes 252 and 254. The dopants and concentrations used to form source/drains 263 and 264 will again depend on the type of device. At this stage of manufacture, silicide contacts 265, which may be fabricated using conventional processes and materials, have also been formed to complete the formation of transistors 266 and 268. The transistors 266, 268 may be configured as all NMOS or PMOS devices, or they may be arranged in a complementary NMOS and PMOS configuration, as shown.

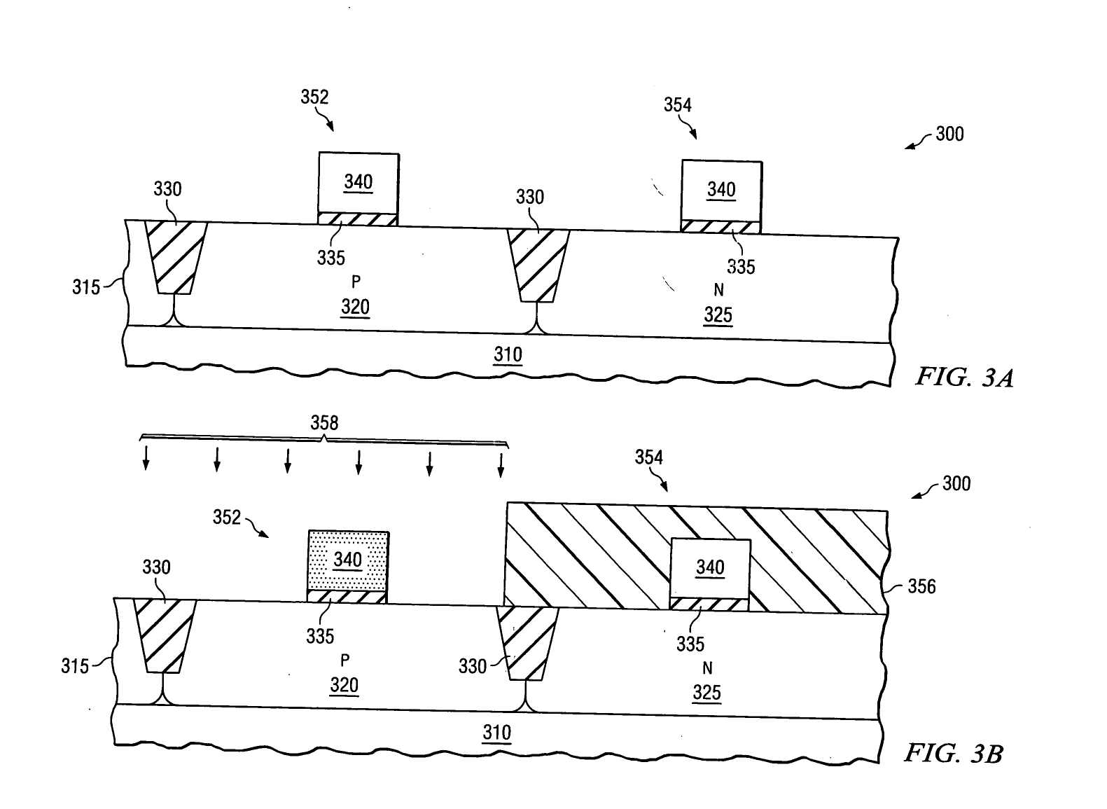

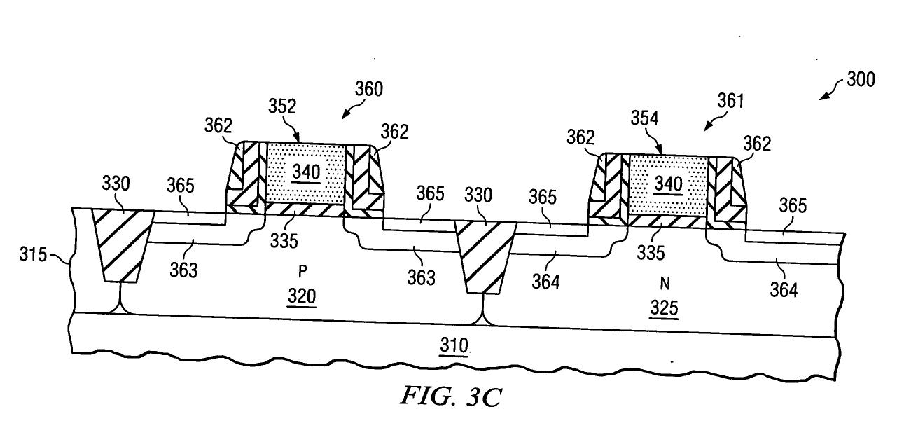

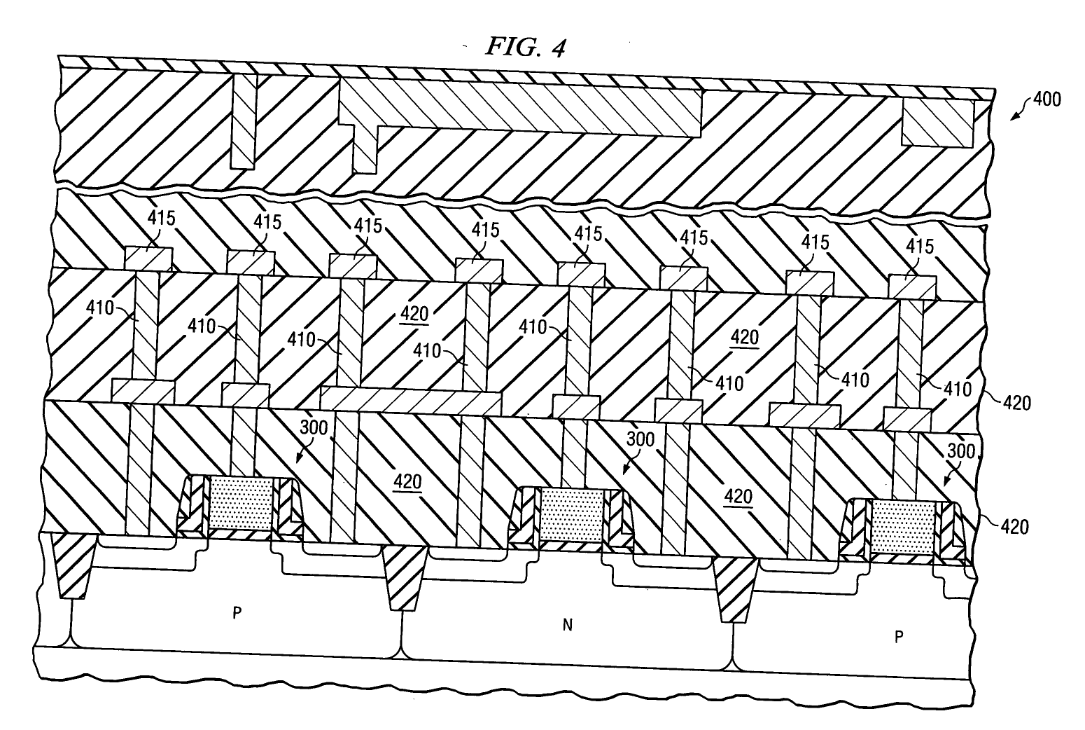

FIG. 3A shows an alternative embodiment of a semiconductor device that incorporates the principles of the invention. In this embodiment, the semiconductor device 300 may include many of the same features as already discussed (shown with similar references). The substrate 310 may be comprised of the same materials previously described. An active layer 315 is located over the substrate 310. The active layer 315 may be a portion of the substrate 310 that is doped to function as an active layer for the device 300, or it may be an epitaxial layer. Wells 320, 325 are located within the active layer 315, and they may be doped with the same type of dopant, or they may be complementary doped wells, as indicated. Isolation structures 330, such as isolation trenches, electrically isolate wells 320, 325 from each other. Any deposition process and material known to those skilled in the art may be used to construct these components.

Also shown are gate dielectric layers 335 and gate layers 340 that have been patterned to form gate electrodes 352 and 354. At this point in the process, the gate electrodes 352 and 354 have not been doped to form an operative gate electrode. The materials and processes used to construct these features may be the same as those discussed above regarding other embodiments. Additionally, neither of the gate dielectric layers 335 have been uniformly fluorinated, as with previous embodiments. Thus, the fluoridation process, which is discussed below, can more appropriately be tailored to the type of intended device. In the illustrated embodiment, the gate electrode 352 may be doped to operate as an NMOS device, while the gate electrode 354 may be doped to operate as a PMOS device. Conventional doping and masking processes may be used to dope the respective devices.

FIG. 3B illustrates the semiconductor device 300 after the deposition and patterning of a patterned mask 356. As with previous embodiments, conventional deposition processes and materials may be used to form the patterned mask 356. The patterned mask 356 protects the gate electrode 354 from a fluorine implantation 358 that is conducted on the exposed gate electrode 352. Thus, fluorine is incorporated into the gate dielectric layer 335 of the gate electrode 352, while the gate dielectric layer 335 under the gate electrode 354 remains protected. The same processes described above regarding other embodiments may be used to incorporate the fluorine into the gate dielectric layer 335.

This embodiment provides a process for selectively incorporating fluorine into a specific gate dielectric layer. This does not exclude incorporation of fluorine into the gate dielectric layer 335 of gate electrode 354. To do so, the patterned mask 356 can be removed and another mask formed over gate electrode 352 to protect it from a fluoridation process conducted on the exposed gate electrode 354. Alternatively, both gate electrodes 352, 354 may be left exposed to the fluorine implantation process 358.

Following the fluorine implantation process 358, conventional processes may be used to appropriately dope the gate electrodes 352 and 354 and complete the semiconductor device 300 as shown in FIG. 3C, which contains many of the same elements as the device shown in FIG. 2G and are similarly numbered. In this embodiment, the semiconductor device 300 includes transistors 360 and 361, which here are respectively arranged in an NMOS and PMOS configuration. The transistors 360 and 361 each include the gate electrodes 352 and 354 and the gate dielectric layers 335. However, in this embodiment, only the gate dielectric layer 335 in the transistor 360 has been fluoridated as described above. The transistors 360 and 361 each further include spacers 362 and source/drains 363 and 364, both of which may be formed with the same material and processes described above regarding other embodiments. At this stage of manufacture, silicide contacts 365, which may be fabricated using conventional processes and materials, have also been formed to complete the formation of transistors 360 and 361.

FIG. 4 is a semiconductor device 400 that is configured as an integrated circuit and incorporates the semiconductor device 300 of FIG. 3C. Only the embodiment of FIG. 3C is shown, but it should be understood that the embodiment of FIG. 2G may also be incorporated into the device 400. The device 400 may be configured into a wide variety of devices, such as CMOS devices, BiCMOS devices, Bipolar devices, as well as capacitors or other types of semiconductor devices. The device 400 may further include passive devices, such as inductors or resistors, or it may also include optical devices or optoelectronic devices. The device 400 includes the various components as discussed above, and conventional interconnect structures 410 and metal lines 415 electrically connect the components of the semiconductor device 300 of FIG. 3C to form an operative IC. The interconnect structures 410 and metal lines 415 may be formed in conventional dielectric layers 420 that are located over the semiconductor device 300. The number of dielectric layers 432 and metal lines 415 will varying with design. Those skilled in the art are familiar with the process and materials that could be used to incorporate the semiconductor device 300 and arrive at the device 400.

Those skilled in the art to which the invention relates will appreciate that other and further additions, deletions, substitutions, and modifications may be made to the described example embodiments, without departing from the invention.

What is claimed is:

1. A method of fabricating a semiconductor device, comprising:
forming a gate dielectric layer on a semiconductor substrate;
depositing a gate layer over the gate dielectric layer; and
incorporating fluorine into the gate dielectric layer;
doping the gate layer after incorporating fluorine into the gate dielectric layer.

2. The method recited in claim 1, wherein incorporating comprises using a thermal anneal conducted at a temperature greater than about 850° C.

3. The method recited in claim 2, wherein a processing temperature used to manufacture the semiconductor device does not exceed about 850° C. after the thermal anneal.

4. The method recited in claim 1, further comprising patterning the gate layer after incorporating the fluorine.

5. The method recited in claim 1, wherein doping comprises doping the gate layer with a dopant dose ranging from about 1e15 atoms/cm² to about 1e16 atoms/cm².

6. The method recited in claim 1, further comprising patterning the gate layer before incorporating the fluorine.

7. The method recited in claim 1, wherein incorporating comprises implanting the fluorine at a dose ranging from about 1e14 atoms/cm² to about 5e15 atoms/cm².

8. The method recited in claim 1, wherein incorporating comprises using implanted fluorine or anneal in fluorine gas and diffusing the fluorine to an interface of the gate dielectric layer and the semiconductor substrate.

9. A method of fabricating a semiconductor device, comprising:
forming gate electrodes over a semiconductor substrate, comprising:
depositing a gate layer over a gate dielectric layer; and
incorporating fluorine into the gate dielectric layer before doping the gate layer;
forming source/drains within the semiconductor substrate and adjacent the gate electrodes;
depositing dielectric layers over the gate electrodes; and
forming interconnects within and over the dielectric electrodes to interconnect the gate electrodes.

10. The method recited in claim 9, wherein incorporating comprises using a thermal anneal conducted at a temperature greater than about 850° C.

11. The method recited in claim 10, wherein a processing temperature used to manufacture the semiconductor device does not exceed about 850° C. after the thermal anneal.

12. The method recited in claim 9, further comprising patterning the gate layer after incorporating the fluorine.

13. The method recited in claim 9, further comprising doping the gate layer after incorporating.

14. The method recited in claim 13, wherein doping comprises doping the gate layer with a dopant dose ranging from about 1e15 atoms/cm² to about 1e16 atoms/cm².

15. The method recited in claim 9, further comprising patterning the gate layer before incorporating the fluorine.

16. The method recited in claim 9, wherein incorporating comprises implanting the fluorine at a dose ranging from about 1e14 atoms/cm² to about 5e15 atoms/cm².

17. The method recited in claim 9, wherein incorporating comprises using implanted fluorine or anneal in fluorine gas and diffusing the fluorine to an interface of the gate dielectric layer and the semiconductor substrate.

18. A semiconductor device, comprising:
a gate dielectric layer on a substrate
a gate layer located over the gate dielectric layer, the gate layer being doped with a dopant;
and fluorine incorporated into the gate dielectric layer prior to the gate layer being doped with the dopant.
